(19) United States
(12) Patent Application Publication
(10) Pub. No.: US 2016/0165722 A1
(43) Pub. Date: Jun. 9, 2016

(54) INTERPOSER SUBSTRATE AND METHOD OF FABRICATING THE SAME

(71) Applicant: PHOENIX PIONEER TECHNOLOGY CO., LTD, Hsinchu County 303 (TW)

(72) Inventors: Che-Wei Hsu, Hsinchu County (TW); Shih-Ping Hsu, Hsinchu County (TW)

(21) Appl. No.: 14/602,373

(22) Filed: Jan. 22, 2015

(30) Foreign Application Priority Data
Dec. 3, 2014 (CN) 201410727333.4

(51) Int. Cl. H05K 1/11; H01L 21/48; H01L 23/498; H05K 3/40; H05K 3/46

(52) U.S. Cl. CPC H05K 1/11; H05K 3/40; H05K 3/4611; H01L 23/49822; H01L 23/49827; H01L 23/49816; H01L 21/4857; H01L 21/4853

(57) ABSTRACT

A method of fabricating an interposer substrate is provided, including: providing a carrier having a first wiring layer and a plurality of conductive pillars disposed on the first wiring layer; forming a first insulating layer on the carrier, with the first conductive pillars being exposed from the first insulating layer; forming on the first conductive pillars a second wiring layer that is electrically connected to the first conductive pillars; forming a plurality of second conductive pillars on the second wiring layer; forming on the first insulating layer a second insulating layer that covers the second wiring layer and the second conductive pillars, with terminal surfaces of the second conductive pillars being exposed from the second insulating layer; and removing the carrier. The first conductive pillars have terminal surfaces in geometric shapes, except for a circle. Therefore, the interposer substrate can have a layout on demands, and can be designed at a designer's will. The present invention also provides the interposer substrate.

### BACKGROUND OF THE INVENTION

1. Field of the Invention

The present invention relates to interposer substrates, and, more particularly, to an interposer substrate used in stacked packages and a method of fabricating the same.

2. Description of Related Art

With the advancement in semiconductor packaging technology, various types of packages of the semiconductor device have been developed, in order to increase electrical functionality and reduce packaging space. For instance, a Package on Package (PoP) is developed having multiple packaging structures, each being stacked on top of the other. This type of package having the property of heterogeneous integration of a System in Package (SiP), is capable of incorporating and integrating various electronic components of different functions such as: memory, central processing unit, graphic processor, image processor and etc., in a package through stacking, thereby is very suitable to be used in various low-profile electronic products.

Early stacked packages are formed by stacking memory packages (memory IC) over the logic packages (logic IC) via a plurality of solder balls. As the demand for light-weight and low profile electronic products, the density of wiring on the memory package increases. The memory package is measured in nanometers; the distance between the contact points are further shortened. However the distances between the logic packages are measured in micrometers, and cannot be miniaturized further to comply with the distances between the memory packages. As a result, even a memory package with high density wiring is provided, there is no suitable logic package to go in concert with the memory package, thereby unable to achieve efficient production of the electronic products.

Accordingly, in order to overcome the above mentioned drawbacks, an interposer substrate is disposed between the memory package and logic package. For instance, the bottom of the interposer is coupled to the logic package having logic chips with high distance, while the top of the interposer substrate is coupled to a memory package having a memory chip of smaller distance.

FIGS. 1A and 1B are cross-sectional views illustrating a method of fabricating an interposer substrate 1 according to the prior art.

As shown in FIG. 1A, a plurality of vias 100 are formed on a carrier board 10 by a laser method.

As shown in FIG. 1B, wiring layers 1 and 14 are formed on the two sides of the carrier board 10, respectively, and the vias 15 are platted with metal to form conductive pillars 12, and electrically connected with the first wiring layer 11 and second wiring layer 14.

Subsequently, insulative protection layers 13 and 16 are formed on the two sides of the carrier board 10 and on the first wiring layer 11 and second wiring layer 14, and a portion of the wiring layers 11 and 14 is exposed for functioning as electrical connection pads.

However, in the method of fabricating the interposer substrate 1, the vias 100 for electrically connecting wirings on each layer are formed by laser, which are then followed by platting to form conductive pillars 12. Since the shapes of the terminal surfaces of the conductive pillars 12 are circular, the conductive pillars 12 must be in circular shapes, thereby limiting the product design.

Hence, there is an urgent need to solve the foregoing problems encountered in the prior art.

### SUMMARY OF THE INVENTION

In view of the above-mentioned drawbacks of the prior art, the present invention provides an interposer substrate, comprising: a first insulating layer having opposing first and second surfaces; a first wiring layer formed in the first insulating layer and exposed from the first surface of the first insulating layer; a plurality of first conductive pillars formed in the first insulating layer and disposed on the first wiring layer, wherein the first conductive pillars have terminal surfaces that are in geometric shapes, except for a circle and exposed from the second surface of the first insulating layer; a second wiring layer formed on the second surface of the first insulating layer and the terminal surfaces of the first conductive pillars and electrically connected with the first conductive pillars; a plurality of second conductive pillars formed on the second wiring layer; and a second insulating layer formed on the second surface of the first insulating layer and encapsulating the second wiring layer and the second conductive pillars, with the terminal surfaces of the second conductive pillars being exposed from the second insulating layer. The present invention further comprises a method of fabricating an interposer substrate, comprising: providing a carrier board having a first wiring layer and a plurality of first conductive pillars formed the first wiring layer, the first conductive pillars having terminal surfaces that are in geometrical shapes, except for a circle; forming on the carrier board a first insulating layer that has opposing first and second surfaces and coupled to the carrier board via the first surface, with terminal surfaces of the first conductive pillars being exposed from the second surface of the first insulating layer; forming on the second surface of the first insulating layer and the terminal surfaces of the first conductive pillars a second wiring layer that is electrically connected with the first conductive pillars; forming a plurality of second conductive pillars on the second wiring layer; forming a second insulating layer on the second surface of the first insulating layer and encapsulating the second wiring layer and the second conductive pillars, with the terminal surfaces of the second conductive pillars being exposed from the second insulating layer; and removing the carrier, such that the first wiring layer is exposed from the first surface of the first insulating layer.

In an embodiment, the entire carrier is removed.

In an embodiment, the first insulating layer is formed on the carrier board by molding, coating or lamination method, and made of a molding compound, a primer or a dielectric material.

In an embodiment, the surface of the first wiring layer is lower than the first surface of the first insulating layer.

In an embodiment, the terminal surfaces of the conductive pillars are flush with the second surface of the first insulating layer.

In an embodiment, the terminal surfaces of the second conductive pillar are a plurality of solder ball pads.

In an embodiment, the terminal surfaces of the second conductive pillars are flush with the surface of the second insulating layer.

In an embodiment, the second insulating layer is formed on the carrier board by molding, coating or lamination method, and made of a molding compound, a primer or a dielectric material.

In an embodiment, a portion of the carrier board is removed, such that the remaining portion of the carrier board functions as a supporting structure formed on the first surface of the first insulating layer.

In summary, in the interposer substrate and the method of fabricating the same according to the present invention the first conductive pillars are formed in any kind of shapes by plating, such that the shape of the terminal surface thereof can be any kind of geometrical shapes other than circular shapes.

Furthermore, as the terminal surfaces of the first conductive pillars can be in all kinds of different geometrical shapes, the layout is made more flexible. Hence, as compared with a conventional interposer substrate, the interposer substrate according to the present invention has finer pitch of the layout, thereby increasing the density of the layout.

### BRIEF DESCRIPTION OF THE DRAWINGS

FIGS. 1A and 1B are schematic cross-sectional views illustrating a method of fabricating an interposer substrate according to the prior art;

FIGS. 2A-2F are schematic cross-sectional views illustrating a method of fabricating an interposer substrate according to the present invention; wherein FIG. 2F′ is another embodiment of FIG. 2F; and

FIGS. 3A-3D are top views showing the first conductive pillars of the interposer substrate according to the present invention.

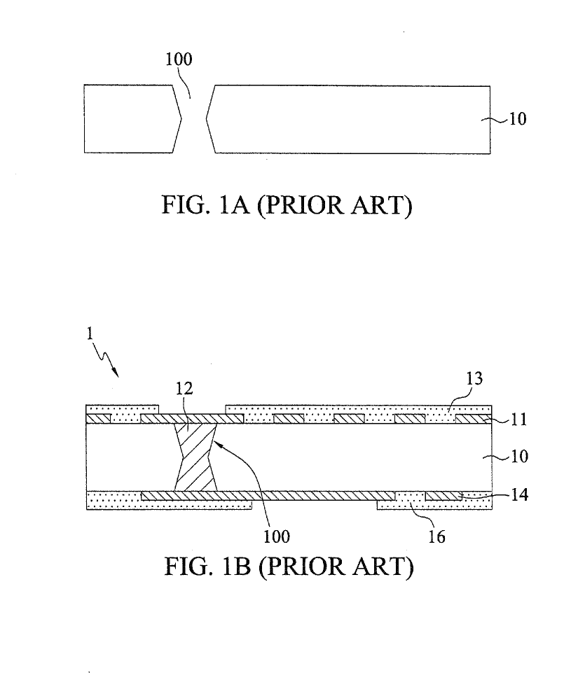

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

It should be noted that all the drawings are not intended to limit the present invention. Various modification and variations can be made without departing from the spirit of the present invention. Further, terms, such as “top”, “first”, “second”, “one” and etc., are merely for illustrative purpose and should not be construed to limit the scope of the present invention.

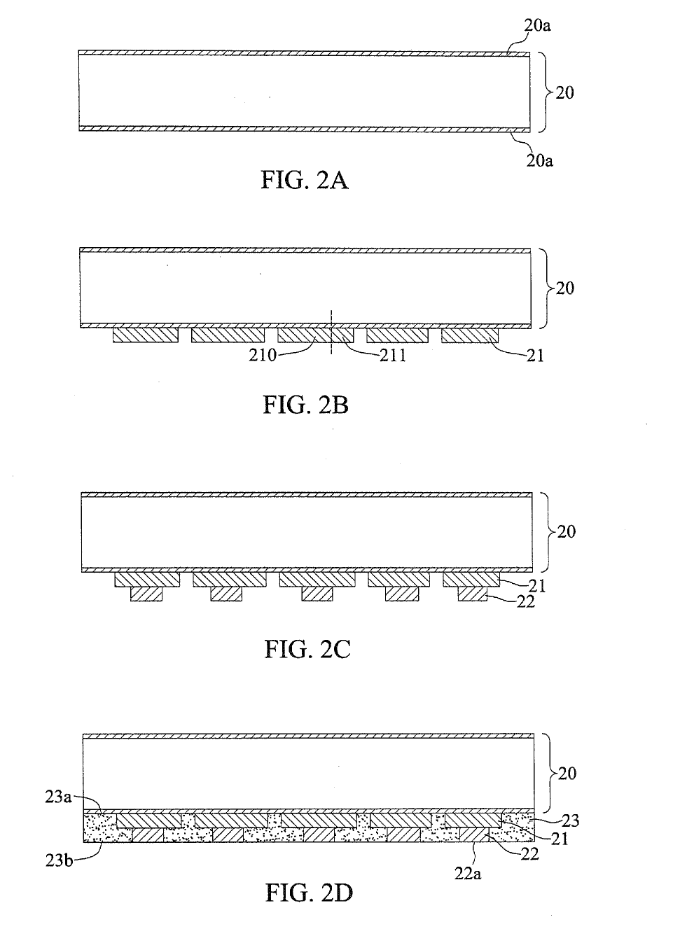

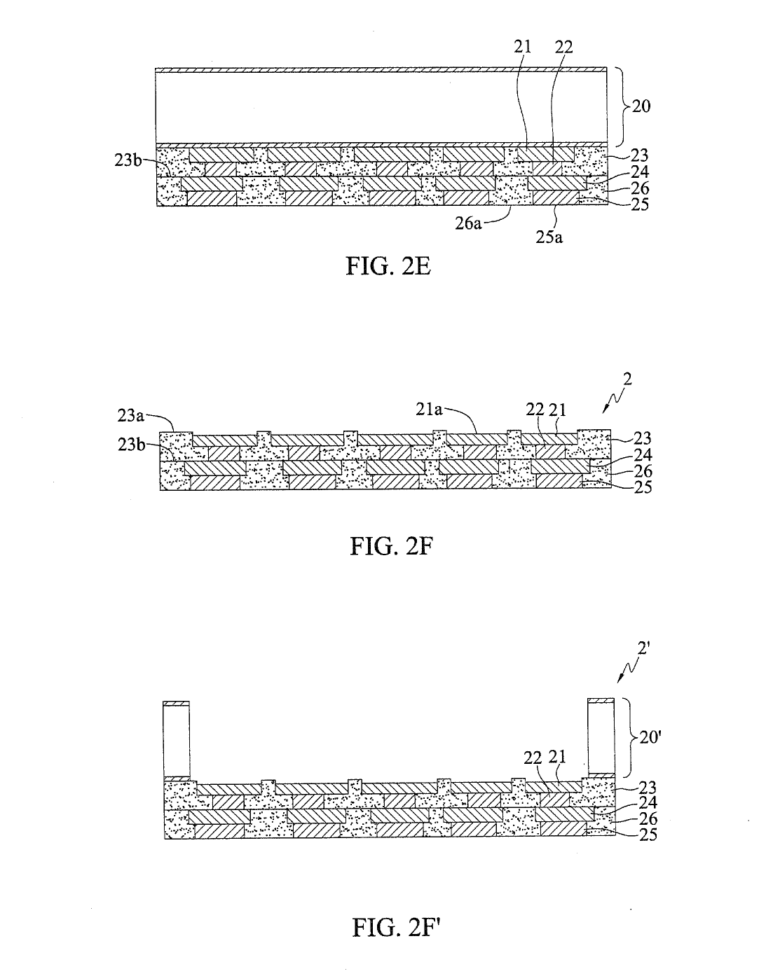

FIGS. 2A-2F are cross-sectional view illustrating a method of fabricating a coreless interposer substrate 2 according to the present invention. In an embodiment, the interposer substrate 2 is a flip-chip scale package (FCCSP).

As shown in FIG. 2A, a carrier board 20 is provided. In an embodiment, the carrier board 20 is, but not limited to, a substrate, such as a copper foil substrate or a silicon containing board. The copper foil substrate is used to exemplify the present embodiment, wherein a metal material 20a is formed on each of the two sides thereof.

As shown in FIG. 2B, a first wiring layer 21 is formed on the carrier 20 through patterning.

In an embodiment, the first wiring layer 21 has a plurality of electrical connection pads 210 and a plurality of conductive traces 211.

As shown in FIG. 2C, through a pattering process, a plurality of conductive pillars 22 are electro-platted on the electrical connection pads 210 of the first wiring layer 21.

In an embodiment, the first conductive pillars 22 are in contact with and electrically connected with the electrical connection pads 210.

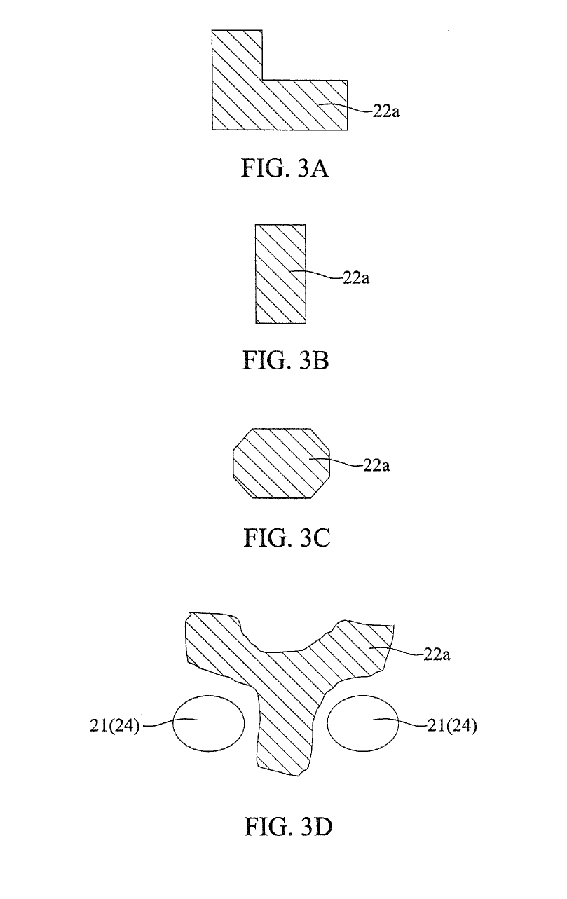

Moreover, the terminal surfaces 22a of the first conductive pillars 22 are in all kinds of different geometrical shapes (not including circular shapes), such as L-shaped (as shown in FIG. 3A), rectangular (as shown in 3B), polygon shapes (as shown in FIG. 3C), or irregular shapes.

As shown in FIG. 2D, a first insulating layer 23 is formed the carrier board 20. The first insulating layer 23 has opposing first and second surfaces 23a and 23b. The first insulating layer 23 is coupled to the carrier board 20 via the first surface 23a of the first insulating layer 23, and the terminal surfaces 22a of the conductive pillars 22 are exposed from the second surface 23b of the first insulating layer 23.

In an embodiment, the first insulating layer 23 is formed on the carrier 20 by a molding, coating or lamination method. The first insulating layer 23 is made of a molding compound, a primer, or a dielectric material such as epoxy.

Moreover, the terminal surfaces 22a of the first conductive pillars are flush with the second surface 23b of the first insulating layer 23.

As shown in FIG. 2E, a second wiring layer 24 is formed on the second surface 23b of the first insulating layer 23 and the terminal surfaces 22a of the conductive pillars 22, followed by forming a plurality of second conductive pillars 25 on the second wiring layer 24, then a second insulating layer 26 is formed on the second surface 23b of the first insulating layer 23, for encapsulating the second conductive pillars 25 and the second wiring layer 24. Meanwhile, the terminal surfaces 25a of the second conductive pillars 25 are exposed from the second insulating layer 26.

In an embodiment, the terminals surfaces 25a of the second conductive pillars 25 function as solder ball pads for coupling with the solder balls (not shown), and the terminal surfaces 25a of the second conductive pillars 25 are exposed from the second insulating layer 26. For instance, the terminal surfaces 25a of the second conductive pillars are flush with the surface 26a of the second insulating layer 26.

In addition, the second insulating layer 26 is formed by a molding, coating or lamination method. The first insulating layer 26 is made of a molding compound, a primer, or a dielectric material such as epoxy.

As shown in FIG. 2F, the entire carrier board 20 is removed, allowing the surface 21a of the first wiring layer 21 to be exposed from the first surface 23a of the first insulating layer 23, and allowing the surface 21a of the first wiring layer 21 to be lower than the first surface 23a of the first insulating layer.

In an embodiment, the metal layer 20a is removed by etching, such that the top surface 21a of the wiring layer 21 is slightly etched away, such that the top surface 21a of the wiring layer 21 slightly lower than the first surface 23a of the first insulating layer 23.

As shown in FIG. 2F′, a patterning process is performed to etch away a portion of the carrier board 20, making the remaining portion of the carrier board 20 functions as a supporting structure 20′, and the surface 21a of the first wiring layer 21 is exposed from the first surface 23a of the first insulating layer 23.

Accordingly, the method of fabricating the present invention is characterized by using a plating method for fabricating the first conductive pillars 22 to function as a conducting medium between different layers (the first wiring layer 21, and second wiring layer 22) and the conductive pillars can be designed in different shapes according to practical needs such that the terminal surface 22a thereof can be in various different geometrical shapes, other than circular shapes.

Moreover, since the terminal surfaces 22a of the first conductive pillars 22 can be designed in different geometrical shapes, the layout of the substrate becomes flexible, compared to the conventional interposer substrate, the interposer substrate 2, 2′ according to the present invention can be fabricated to have the layout with finer pitch, thereby increasing the density of the layout.

The present invention further provides an interposer substrate 2, 2′, including: a first insulating layer 23, a first wiring layer 21, a plurality of first conductive pillars 22, a second wiring layer 24, a plurality of second conductive pillars 25, and a second insulating layer 26.

The first insulating layer 23 has opposing first and second surfaces 23a and 23b, and the first insulating layer 23 is made of a molding compound, an epoxy resin or a dielectric material.

The first wiring layer 21 is embedded in the first insulating layer 23 and exposed from the first surface 23a of the first insulating layer 23, and the surface 21a of the first wiring layer 21 is made lower than the first surface 23a of the first insulating layer 23.

The first conductive pillars 22 are formed on the first wiring layer 21 in the first insulating layer 23 and to the terminal surfaces 22a of the first conductive pillars 22 are exposed from the second surface 23b of the first insulating layer 23 and flush with the second surface 23b of the first insulating layer 23. The terminal surfaces 22a of the first conductive pillars 22 are formed in any geometrical shapes, but not including circular shapes.

The second wiring layer 24 is formed on the second surface 23b of the first insulating layer 23 and the terminal surfaces 22a of the first conductive pillars 22 and electrically connected to the first conductive pillars 22.

The second conductive pillars 25 are formed on the second wiring layer 24.

The second insulating layer 26 is formed on the second surface 23b of the first insulating layer 23, and encapsulating the second conductive pillars 25 and the second wiring layer 24, allowing the terminal surfaces 25a of the second conductive pillars 25 to be exposed from the second insulating layer 26.

In an embodiment, the terminal surfaces 25a of the second conductive pillars 25 are flush with the surface 26a of the second insulating layer 26.

In an embodiment, the interposer substrate 2′ further comprises a supporting structure 20′ formed on the first surface 23a of the first insulating layer 23.

In summary, the interposer substrate and a method of fabricating the same according to the present invention are widely used in stacked packages having fine pitch and high pin counts, and are particularly desired when miniaturization, high functionality, high speed, and high memory are needed.

Moreover, the interposer substrate 2, 2′ according to the present invention utilizes the first wiring layer 21 to couple with the logic package or memory package, and the second conductive pillars 25 to couple with the logic package or memory package.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. An interposer substrate, comprising:
a first insulating layer having opposing first and second surfaces;
a first wiring layer formed in the first insulating layer and exposed from the first surface of the first insulating layer;
a plurality of first conductive pillars formed in the first insulating layer and disposed on the first wiring layer, wherein the first conductive pillars have terminal surfaces that are in geometric shapes, except for a circle, and exposed from the second surface of the first insulating layer;
a second wiring layer formed on the second surface of the first insulating layer and the first conductive pillars and electrically connected with the first conductive pillars;
a plurality of second conductive pillars formed on the second wiring layer; and
a second insulating layer formed on the second surface of the first insulating layer and encapsulating the second wiring layer and the second conductive pillars, with terminal surfaces of the second conductive pillars being exposed from the second insulating layer.

2. The interposer substrate of claim 1, wherein the first insulating layer is made of a molding compound, a primer or a dielectric material.

3. The interposer substrate of claim 1, wherein the first wiring layer has a surface lower than the first surface of the first insulating layer.

4. The interposer substrate of claim 1, wherein the terminal surfaces of the first conductive pillars are flush with the second surface of the first insulating layer.

5. The interposer substrate of claim 1, wherein the terminal surfaces of the second conductive pillars function as a plurality of solder ball pads.

6. The interposer substrate of claim 1, wherein the terminal surfaces of the second conductive pillars are flush with a surface of the second insulating layer.

7. The interposer substrate of claim 1, wherein the second insulating layer is made of a molding compound, a primer or a dielectric material.

8. The interposer substrate of claim 1, further comprising a supporting structure formed on the first surface of the first insulating layer.

9. A method of fabricating an interposer substrate, comprising:
providing a carrier board having a first wiring layer and a plurality of first conductive pillars formed on the first wiring layer, wherein the first conductive pillars have terminal surfaces that are in geometrical shapes, except for a circle;
forming on the carrier board a first insulating layer that has opposing first and second surfaces and coupled to the carrier board via the first surface, with terminal surfaces of the first conductive pillars being exposed from the second surface of the first insulating layer;
forming on the second surface of the first insulating layer and the terminal surfaces of first conductive pillars a second wiring layer that is electrically connected with the first conductive pillars;
forming a plurality of second conductive pillars on the second wiring layer;
forming a second insulating layer on the second surface of the first insulating layer and encapsulating the second wiring layer and the second conductive pillars, with terminal surfaces of the second conductive pillars being exposed from the second insulating layer; and
removing the carrier to expose the first wiring layer from the first surface of the first insulating layer.

10. The method of claim 9, wherein the first insulating layer is formed on the carrier board by molding, coating or lamination method.

11. The method of claim 9, wherein the first wiring layer has a surface lower than the first surface of the first insulating layer.

12. The method of claim 9, wherein the terminal surfaces of the first conductive pillars are flush with the second surface of the first insulating layer.

13. The method of claim 9, wherein the terminal surfaces of the second conductive pillars function as a plurality of solder ball pads.

14. The method of claim 9, wherein the terminal surfaces of the second conductive pillars are flush with a surface of the second insulating layer.

15. The method of claim 9, wherein the second insulating layer is formed on the carrier board by molding, coating or lamination method.

16. The method of claim 9, wherein the entire carrier board is removed.

17. The method of claim 9, wherein a portion of the carrier board is removed, allowing the remaining portion of the carrier board to function as a supporting structure.
